(19) United States
(12) Patent Application Publication
(10) Pub. No.: US 2026/0308720 A1
(43) Pub. Date: Oct. 8, 2026

(54) METHOD OF MAKING AND LIMITING COLOR CHANGE IN A GOLD ALLOY

(71) Applicant: Nivarox-FAR S.A., Le Locle (CH)

(72) Inventors: Jonas VANNOD, Bienne (CH); Vincent FAYS, Saint-Blaise (CH); Christian CHARBON, Chézard-St-Martin (CH)

(73) Assignee: Nivarox-FAR S.A., Le Locle (CH)

(21) Appl. No.: 19/715,415

(22) Filed: Jun. 22, 2026

Related U.S. Application Data
(63) Continuation of application No. 18/163,991, filed on Feb. 3, 2023, now abandoned.

(30) Foreign Application Priority Data
Mar. 18, 2022 (EP) 22163092.4

(51) Int. Cl. C22C 5/02; A44C 25/00

(52) U.S. Cl. CPC C22C 5/02; A44C 25/00

(57) ABSTRACT

A method of making and/or limiting color change of an annealed gold alloy, may include: alloying metals including, in weight percent, gold in a range of from 73 to 77%, silver in a range of from 20 to 24.5%, palladium and/or platinum in a total percentage in a range of from 0.5 to 5%, to obtain a raw allow; and annealing the raw alloy at a temperature in a range of from 550 to 750° C. for a time in a range of from 5 to 30 minutes, to obtain the annealed gold alloy having a hardness in a range of from 35 to 60 HV1. The color change of such an annealed gold alloy after 4 days may be lower than a 2N 18K gold having 75 wt. % gold, 16 wt. % silver, and 9 wt. % copper.

### CROSS-REFERENCE TO RELATED APPLICATIONS

The present application is a continuation of U.S. Ser. No. 18/163,991, filed on Feb. 3, 2023, and published as US 2023/0295774 A1, which claims the benefit of the filing date of European Appl. No. 22163092.4, filed on Mar. 18, 2022, the content of each of which is incorporated by reference.

### TECHNICAL FIELD OF THE INVENTION

The present invention relates to a gold alloy and more specifically to a green gold alloy. It also relates to an item including a timepiece, made wholly of this alloy or comprising on the surface a coating of this alloy.

### TECHNOLOGICAL BACKGROUND

Colored 18K gold alloys are highly sought-after for the production of timepieces. The green gold alloy compositions available in the literature all contain silver and optionally zinc, copper, cadmium or a combination of several of these elements.

The addition of silver in a large proportion is the main parameter for ensuring the strongest possible tint. Thus, the most promising composition for 18K green gold alloys is that of the alloy Au750Ag250, with 75% Au and 25% Ag by weight, also known as electrum. However, silver dulls very quickly, and this represents one of the main disadvantages of this alloy category.

### SUMMARY OF THE INVENTION

An aim of the invention is that of remedying the disadvantage cited above by proposing a novel green gold alloy with an enhanced tarnishing resistance.

For this purpose, the chemical composition of the gold alloy has been adapted. The gold alloy thus developed is an 18 carat alloy comprising silver, palladium and/or platinum.

More specifically, the gold alloy comprises, by weight, between 73% and 77% gold, between 20% and 24.5% silver, palladium and/or platinum with a total percentage for these two elements between 0.5% and 5%.

Advantageously, the invention relates to a ternary gold alloy consisting of gold, silver and palladium. Optionally, it can contain in small quantities, that is not more than 0.05% by weight for all the elements, one or more elements chosen from iridium, rhenium and ruthenium.

The addition of palladium makes it possible to obtain a similar tint to that of electrum while drastically reducing tarnishing of the alloy over time. A similar effect is observed with the addition of platinum.

Further features and advantages of the invention will become more apparent upon reading the following detailed description, with reference to the appended drawings.

### BRIEF DESCRIPTION OF THE DRAWINGS

FIG. 1 represents in the CIELAB color space the parameters a* and b* for the alloys according to the invention and that according to the prior art.

FIG. 2 represents the change of color (ΔE) as a function of time for an alloy according to the invention and two reference alloys.

FIG. 3 represents a dial made of the gold alloy according to the invention.

### DETAILED DESCRIPTION OF THE INVENTION

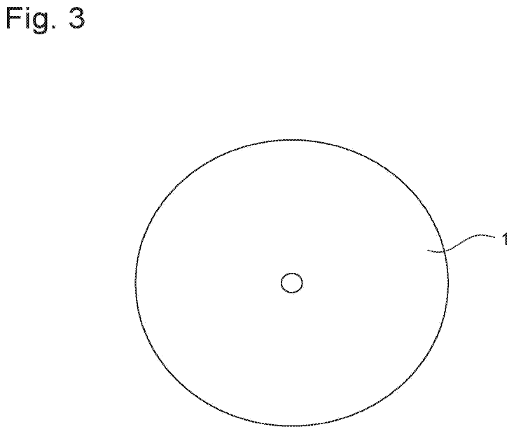

The present invention relates to an 18 carat gold alloy more specifically intended for an application in the field of watchmaking or jewelry. It thus also relates to timepieces or pieces of jewelry made of this alloy. The term timepieces denotes both casing components such as a middle, a back, a bezel, a push-piece, a bracelet link, a flange, a dial, a hand, a dial index, an oscillating mass, etc., and movement components such as a plate, a bridge or a balance. According to the invention, said timepieces or pieces of jewellery are made wholly of said gold alloy or include on the surface a coating made of said gold alloy. In the case of an external casing component, the component is preferably coated with said gold alloy. In the case of an internal casing component, said component is made wholly or coated with said gold alloy. In the case of a coating, by way of example, the substrate can be made of brass or gold, for example, 18 carats. A more specific example is a dial 1 made wholly of said alloy or coated with said alloy, as shown in FIG. 3.

More generally, said gold alloy can be used wholly or on the surface for any item. The field of application of the gold alloy according to the invention also covers the targets used in coating processes such as physical vapor deposition (PVD).

The gold alloy according to the invention comprises, by weight, between 73% and 77% gold, between 20% and 24.5% silver, palladium and/or platinum with a total percentage for these two elements between 0.5% and 5%.

Advantageously, the gold alloy comprises, by weight, between 73% and 77% gold, between 21% and 24.3% silver, palladium and/or platinum with a total percentage for these two elements between 0.7% and 4%.

Preferably, the gold alloy comprises, by weight, between 73.5% and 76.5% gold, between 22.5% and 24.3% silver, palladium and/or platinum with a total percentage for these two elements between 0.7% and 2.5%.

More preferably, the gold alloy comprises, by weight, between 74% and 76% gold, between 23.5% and 24.3% silver, palladium and/or platinum with a total percentage for these two elements between 0.7% and 1.5%.

Furthermore, the gold alloy optionally comprises, by weight, between 0 and 0.05% (inclusive) of one or more elements chosen from iridium, rhenium and ruthenium, the 0-0.05% range covering the total percentage of the or these element(s). Advantageously, the gold alloy comprises 0.0025% iridium by weight.

Preferably, the gold alloy consists in the proportions cited above of gold, silver, palladium and/or platinum and optionally of one or more of the elements chosen from iridium, rhenium and ruthenium.

To prepare the gold alloy, the different elements of the composition are melted before being cast. The cast ingot is then shaped by channel rolling, flat rolling, drawing or wire-drawing. It is deformed with a cold-working rate between 10% and 80% divided into several passes with, optionally, intermediate annealing operations carried out within a temperature range between 550° C. and 750° C., for a time between 5 minutes and 30 minutes. In the examples hereinafter, the samples are annealed at a temperature of 650° C. for 30 minutes. After cooling, the blanks are sized, for example, by machining. It can also be envisaged that the blanks be in the cold-worked state to facilitate machining, an annealing operation optionally being carried out after machining.

In the context of a coating with said gold alloy on a substrate, the deposition process can be a physical vapor deposition (PVD) or chemical vapor deposition (CVD) process.

The alloys obtained after deformation and annealed or in the form of coating have in the CIELAB color space (as per the CIE No. 15, ISO 7724/1, DIN 5033 Teil 7, ASTM E-1164 standards) a value a* between −7 and 1, preferably between −5 and 0, and a value b* between 20 and 32, preferably between 22 and 30; the values a* and b* defining the tint of the alloy together. Furthermore, they have a value L between 80 and 95, the values L*a*b* defining the color of the alloy together. According to the present invention, emphasis is placed more specifically on the values a* and b* which define the tint of the alloy. According to the invention, the gold alloy has a green tint.

These gold alloys have a hardness between 35 and 60 HV1, preferably between 40 and 55 HV1 in the cold-worked state. These gold alloys have a density between 15 and 17.

Table 1 gives the composition by weight of the reference electrum 18 carat gold alloy and of four 18 carat gold alloys according to the invention. The colorimetric values and the hardness (HV1) measured are also presented in Table 1 for certain compositions on deformed samples annealed at 650° C. for 30 minutes. The colorimetric values L*a*b* were measured with a KONICA MINOLTA CM-2600d spectrophotometer with an illuminant D65 and a viewing angle of 10°.

TABLE 1

| | Compositions | | | | | | | | |
|---|---|---|---|---|---|---|---|---|---|
| | (% by wt.) | | | | | Hardness | Colorimetry | | |
| | Au | Ag | Pd | Pt | Density | HV1 | L | a | b |
| Refer- | 75.06 | 24.94 | 0 | 0 | 16 | 46 | 92.5 | −3.68 | 28.04 |
| ence | | | | | | | | | |
| Inven- | 75.06 | 23.94 | 1 | 0 | 16 | 47 | 90.52 | −2.25 | 26.28 |
| tion | 75.06 | 22.94 | 2 | 0 | 16 | 49 | 89.27 | −1.01 | 24.36 |
| | 75.06 | 21.94 | 3 | 0 | 16 | / | / | / | / |
| | 75.06 | 23.94 | 0 | 1 | 16 | / | / | / | / |

Little variation of the hardness is observed with values between 45 and 50 HV1 in the annealed state.

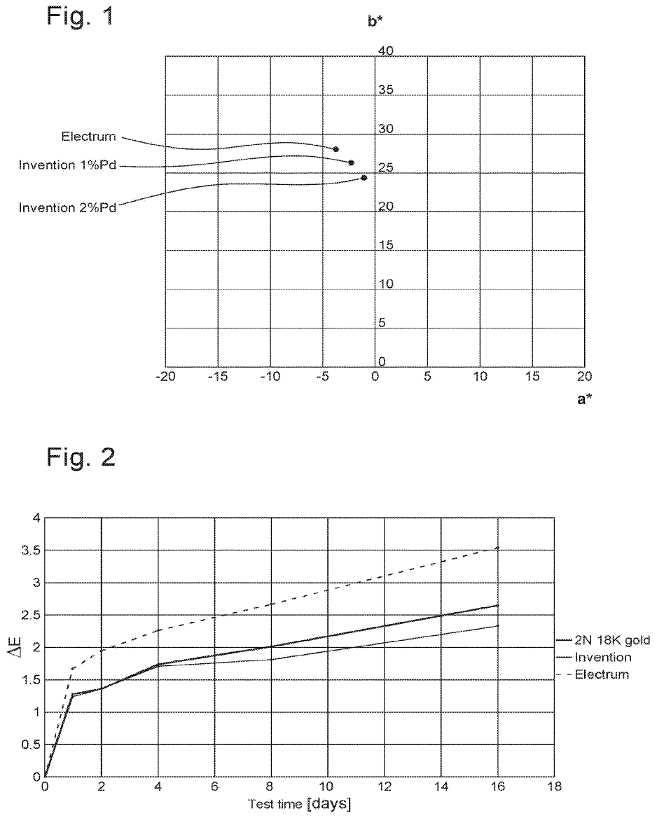

In FIG. 1, it is observed that the addition of palladium only alters the tint slightly with values a* and b* which are similar to those of electrum.

FIG. 2 represents Delta E which is the color variation over time over a period of 16 days for two reference samples which are electrum and one 2N 18K gold (75% gold, 16% silver and 9% copper by weight) and a gold alloy according to the invention comprising silver and palladium with a percentage by weight of palladium of 2%. Delta E is calculated on the basis of the values L*a*b* as follows where

$${L}_{1}^{*} , {a}_{1}^{*} and {b}_{1}^{*}$$

refer to the values at the time 0.

$$Δ {E}^{*} = {[ {( {L}_{2}^{*} - {L}_{1}^{*} )}^{2} + {( {a}_{2}^{*} - {a}_{1}^{*} )}^{2} + {( {b}_{2}^{*} - {b}_{1}^{*} )}^{2} ]}^{1 / 2}$$

It is noted that the addition of palladium reduces tarnishing significantly, which makes it comparable, or less susceptible than 2N gold to tarnishing.

1. A method of limiting color change of an annealed gold alloy, the method comprising:
alloying metals comprising, in weight percent, gold in a range of from 73 to 77%, silver in a range of from 20 to 24.5%, palladium and/or platinum in a total percentage in a range of from 0.5 to 5%, to obtain a raw allow; and
annealing the raw alloy at a temperature in a range of from 550 to 750° C. for a time in a range of from 5 to 30 minutes, to obtain the annealed gold alloy having a hardness in a range of from 35 to 60 HV1.

2. The method of claim 1, wherein the color change of the annealed gold alloy after 4 days is lower than a 2N 18K gold having 75 wt. % gold, 16 wt. % silver, and 9 wt. % copper.

3. The method of claim 1, wherein the gold is present in the annealed gold alloy a range of from 73.5 to 76.5 wt. %.

4. The method of claim 1, wherein the gold is present in the annealed gold alloy a range of from 74 to 76 wt. %.

5. The method of claim 1, wherein the silver is present in the annealed gold alloy a range of from 21 to 24.3 wt. %.

6. The method of claim 1, wherein the silver is present in the annealed gold alloy a range of from 22.5 to 24.3 wt. %.

7. The method of claim 1, wherein the silver is present in the annealed gold alloy a range of from 23.5 to 24.3 wt. %.

8. The method of claim 1, wherein the palladium and/or platinum are present in the annealed gold in a total percentage in a range of from 0.7 to 4%.

9. The method of claim 1, wherein the palladium and/or platinum are present in the annealed gold in a total percentage in a range of from 0.7 to 2.5%.

10. The method of claim 1, wherein the palladium and/or platinum are present in the annealed gold in a total percentage in a range of from 0.7 to 1.5%.

11. The method of claim 1, wherein the annealed gold comprises the palladium.

12. The method of claim 1, wherein the annealed gold comprises the platinum.

13. The method of claim 1, wherein the annealed gold comprises the palladium and the platinum.

14. The method of claim 1, wherein the annealed gold further comprises iridium.

15. The method of claim 1, wherein the annealed gold further comprises iridium, rhenium, and/or ruthenium in a range of from more than 0 to 0.05 wt. %.

16. The method of claim 1, further comprising shaping the raw material by channel rolling, flat rolling, drawing, or wire-drawing.

17. The method of claim 16, further comprising:
deforming by cold-working in a range of from 10 to 80%, divided into more than one pass.

18. The method of claim 17, further comprising:
intermediately annealing, between cold-working passes, in a temperature range of from 550 to 750° C., for a time in a range of from 5 to 30 minutes.

19. A method of producing an annealed gold alloy, the method comprising:
alloying metals comprising, in weight percent, gold in a range of from 73 to 77%, silver in a range of from 20 to 24.5%, palladium and/or platinum in a total percentage in a range of from 0.5 to 5%, to obtain a raw allow; and
annealing the raw alloy at a temperature in a range o from 550 to 750° C. for a time in a range of from 5 to 30 minutes, to obtain the annealed gold alloy having a hardness in a range of from 35 to 60 HV1.

20. The method of claim 19, wherein the annealed gold alloy, in CIELAB color space per CIE No. 15, ISO 7724/1, DIN 5033 Teil7, ASTM E-1164 standards, has
a* in a range of from −7 to 1,
b* in a range of from 20 to 32,
L* in a range of from 80 to 95.
